(19) United States
(12) Patent Application Publication
(10) Pub. No.: US 2022/0373272 A1
(43) Pub. Date: Nov. 24, 2022

(54) HEAT DISSIPATION MEMBER

(71) Applicants: Nidec Corporation, Kyoto (JP); Nidec Chaun-Choung Technology Corporation, New Taipei City (TW)

(72) Inventors: Yi-Huan KAO, New Taipei City (TW); Kazuhiro NISHIKAWA, Kyoto (JP)

(21) Appl. No.: 17/743,514

(22) Filed: May 13, 2022

(30) Foreign Application Priority Data
May 19, 2021 (JP) 2021-084969
Oct. 11, 2021 (JP) 2021-166875

(51) Int. Cl. F28F 3/02; F28D 9/00; F28D 21/00

(52) U.S. Cl. CPC F28F 3/027; F28D 9/0068; F28D 21/00; F28D 2021/0068; F28F 2215/08; F28F 2215/04

(57) ABSTRACT

A heat dissipator includes a plate-shaped base portion extending in a first direction along a refrigerant flowing direction and in a second direction orthogonal to the first direction and has a thickness in a third direction orthogonal to the first direction and the second direction, and fin groups including fins arranged in the second direction, protruding from the base portion to one side in the third direction and extending in the first direction. One of the fins includes a spoiler with an opposing surface that opposes one side in the first direction that is a downstream side in the refrigerant flowing direction. A number of the spoilers included in each of the fins in a same second direction position in the fin groups increases toward the one side in the first direction.

### CROSS-REFERENCE TO RELATED APPLICATIONS

The present application claims priority under 35 U.S.C. § 119 to Japanese Patent Application No. 2021-084969, filed on May 19, 2021, and Japanese Patent Application No. 2021-166875, filed on Oct. 11, 2021, the entire contents of which are hereby incorporated herein by reference.

### 1. Field of the Invention

The present disclosure relates to a heat dissipator.

### 2. Background

Conventionally, a heat dissipator is used for cooling a heating element. The heat dissipator includes a base part and a plurality of fins. The plurality of fins protrude from the base part. When a refrigerant such as water flows between adjacent fins in the plurality of fins, heat of the heating element moves to the refrigerant.

In the conventional heat dissipator, when a plurality of heating elements are arranged in a direction where the refrigerant flows, the temperature of the refrigerant increases due to heat transfer toward the downstream side, and therefore a temperature difference generated between the heating elements is a problem.

### SUMMARY

An example embodiment of a heat dissipator of the present disclosure includes a plate-shaped base portion that extends in a first direction along a direction where a refrigerant flows and in a second direction orthogonal to the first direction and has a thickness in a third direction orthogonal to the first direction and the second direction, and fin groups that include fins arranged in the second direction and protruding from the base portion to one side in the third direction and extending in the first direction, the fin groups being arranged side by side in the first direction. At least one of the fins included in at least one of the fin groups includes a spoiler that includes an opposing surface that opposes one side in the first direction that is a downstream side in a refrigerant flowing direction. A number of the spoilers included in each of the fins in a same second direction position in the fin groups increases toward the one side in the first direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view of a heat dissipator according to an example embodiment of the present disclosure.

FIG. 2 is a side view of the heat dissipator as viewed to one side in the second direction.

FIG. 3 is a plan view of the heat dissipator as viewed from one side in the third direction.

FIG. 4 is a partially enlarged view of an upstream side fin group in the heat dissipator.

FIG. 5 is a partially enlarged view showing a configuration in the vicinity between the upstream side fin group and a center fin group.

FIG. 6 is a view schematically showing a flow of a refrigerant in the vicinity of a second fin according to an example embodiment of the present disclosure.

FIG. 7 is a partially enlarged view showing a configuration in the vicinity of an end portion fin group in the upstream side fin group.

FIG. 8 is a view schematically showing a flow of the refrigerant in the vicinity of a third fin according to an example embodiment of the present disclosure.

FIG. 9 is a partially enlarged view showing a configuration in the vicinity between the upstream side fin group and the center fin group.

FIG. 10 is a side view of the center fin group.

FIG. 11 is a perspective view showing a configuration example of a spoiler according to an example embodiment of the present disclosure.

FIG. 12 is a side view showing a modification of the arrangement number of the spoilers.

FIG. 13 is a side view showing a modification of the arrangement number of the spoilers.

FIG. 14 is a side view of a downstream side fin group according to an example embodiment of the present disclosure.

FIG. 15 is a side view of the downstream side fin group.

FIG. 16 is a side view of the center fin group.

FIG. 17 is a side sectional view showing a gap between the spoiler and each of a bottom plate portion and a top plate portion.

FIG. 18 is a side view showing an example in which the spoiler is provided with a bottom surface recess portion.

FIG. 19 is a perspective view showing an example of a fin provided with the bottom surface recess portion.

FIG. 20 is a view showing an example in which the bottom surface recess portion and the spoiler are viewed in the third direction.

FIG. 21 is a view showing a first form of the positional relationship between the spoiler and the bottom surface recess portion.

FIG. 22 is a view showing a second form of the positional relationship between the spoiler and the bottom surface recess portion.

FIG. 23 is a view showing a third form of the positional relationship between the spoiler and the bottom surface recess portion.

FIG. 24 is a view showing a fourth form of the positional relationship between the spoiler and the bottom surface recess portion.

FIG. 25 is a view showing a fifth form of the positional relationship between the spoiler and the bottom surface recess portion.

FIG. 26 is a side sectional view showing an example of the spoiler at an inclination angle close to vertical.

FIG. 27 is a side sectional view showing an example in which the bottom plate portion and the top plate portion are provided with a notch.

FIG. 28 is a side view showing an example in which the base portion is provided with the bottom surface recess portion.

### DETAILED DESCRIPTION

Hereinafter, example embodiments of the present disclosure will be described with reference to the drawings.

In the drawings, with the first direction as an X direction, X1 indicates one side in the first direction, and X2 indicates the other side in the first direction. The first direction is along a direction F in which a refrigerant W flows, and the downstream side is indicated by F1 and the upstream side is indicated by F2. With the second direction orthogonal to the first direction as a Y direction, Y1 indicates one side in the second direction, and Y2 indicates the other side in the second direction. With the third direction orthogonal to the first direction and the second direction as a Z direction, Z1 indicates one side in the third direction, and Z2 indicates the other side in the third direction. Note that the above-described “orthogonal” also includes intersection at an angle slightly shifted from 90 degrees. Each of the above-described directions does not limit a direction when a heat dissipator 1 is incorporated in various devices.

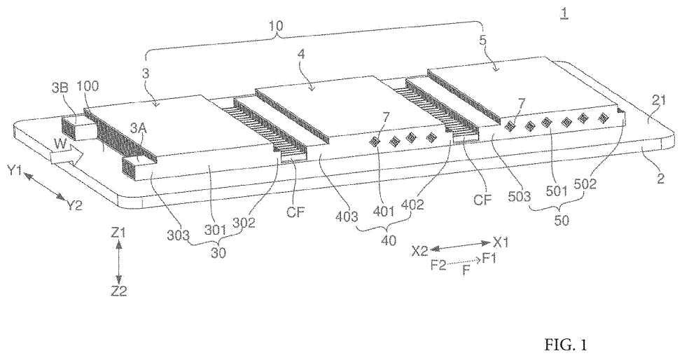

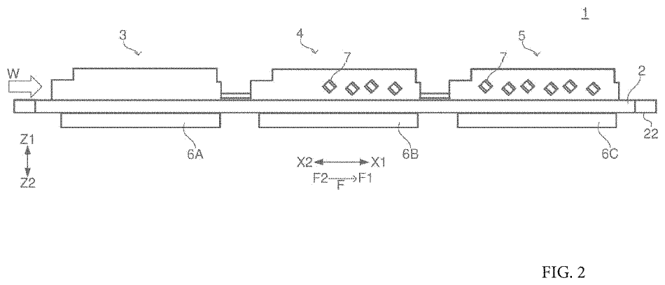

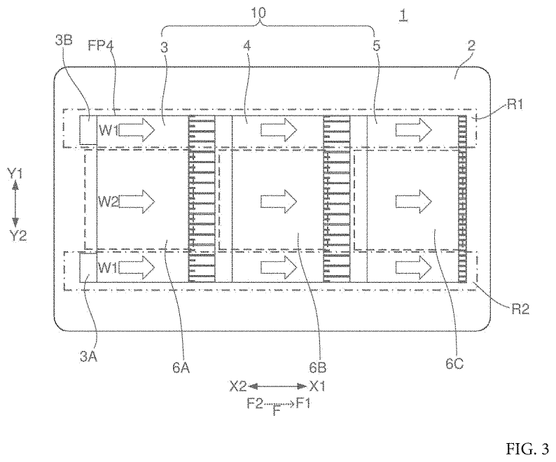

FIG. 1 is a perspective view of the heat dissipator 1 according to an example embodiment of the present disclosure. FIG. 2 is a side view of the heat dissipator 1 as viewed to one side in the second direction. FIG. 3 is a plan view of the heat dissipator 1 as viewed from one side in the third direction.

The heat dissipator 1 is a device that cools a plurality of heating elements 6A, 6B, and 6C (FIGS. 2 and 3) arranged in the first direction. The heating elements 6A, 6B, and 6C are power transistors of an inverter included in a traction motor for driving wheels of a vehicle, for example. The power transistor is, for example, an insulated gate bipolar transistor (IGBT). In this case, the heat dissipator 1 is mounted on a traction motor. The number of heating elements may be plural other than three.

The heat dissipator 1 includes a base portion 2 and a heat dissipation fin part 10. The heat dissipation fin part 10 includes an upstream side fin group 3, a center fin group 4, and a downstream side fin group 5.

The base portion 2 has a plate shape that extends in the first direction and the second direction and has a thickness in the third direction. The base portion 2 is made of a metal having high thermal conductivity, for example, a copper plate.

The upstream side fin group 3, the center fin group 4, and the downstream side fin group 5 are arranged on one side in the third direction of the base portion 2 from the other side in the first direction (upstream side) in toward one side in the first direction (downstream side) in this order. As described later, the fin groups 3, 4, and 5 are fixed to a surface 21 on one side in the third direction of the base portion 2 by brazing, for example.

The heating elements 6A, 6B, and 6C are in direct or indirect contact with a surface 22 on the other side in the third direction of the base portion 2 (FIG. 2). When viewed in the third direction, the heating elements 6A, 6B, and 6C overlap the fin groups 3, 4, and 5, respectively (FIG. 3).

When the refrigerant W is supplied to the upstream side fin group 3 from the upstream side relative to the upstream side fin group 3, the refrigerant W sequentially flows through the fin groups 3, 4, and 5 and is discharged from the downstream side fin group 5 to the downstream side. At this time, the heats generated from the heating elements 6A, 6B, and 6C move to the refrigerant W via the base portion 2 and the fin groups 3, 4, and 5, respectively. This cools the heating elements 6A, 6B, and 6C.

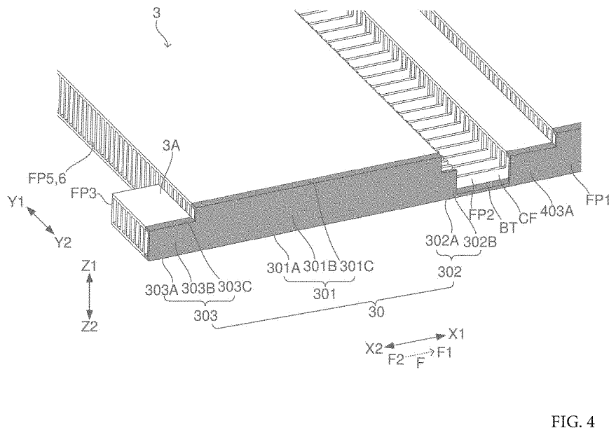

Here, an example of a specific method of forming the heat dissipation fin part 10 (fin groups 3, 4, and 5) will be described also with reference to FIG. 4. FIG. 4 is a partially enlarged view of the upstream side fin group 3 in the heat dissipator 1.

The fin groups 3, 4, and 5 are configured as so-called stacked fins by arranging a plurality of fin plates FP in the second direction. The fin plate FP is formed of a metal plate extending in the first direction, and is formed of, for example, a copper plate. Each of the fin plates FP1 to FP6 illustrated in the drawing is a type of fin plate FP. That is, FP is used as an overall reference sign of the fin plate.

In order to understand the fin plate FP, FIG. 4 indicates, by hatching, the fin plate FP positioned on the most other side in the second direction. The fin plate FP includes fins 30, 40, and 50. Note that the fins 40 and 50 are shown in FIG. 1. The fins 30, 40, and 50 constitute the fin groups 3, 4, and 5, respectively.

As shown in FIG. 4, the fin 30 has a first fin 301, a second fin 302, and a third fin 303.

The first fin 301 has a bottom plate portion 301A, a wall part 301B, and a top plate portion 301C. The wall part 301B has a plate shape extending in the first direction and the third direction with the second direction as the thickness direction. The bottom plate portion 301A is formed by being bent from an end portion on the other side in the third direction of the wall part 301B to one side in the second direction. The top plate portion 301C is formed by being bent from an end portion on one side in the third direction of the wall part 301B to one side in the second direction. The bottom plate portion 301A and the top plate portion 301C oppose each other in the third direction. Due to this, the first fin 301 has a U-shaped cross section in a cut surface orthogonal to the first direction.

The bottom plate portion 301A and bottom plate portions 302A and 303A described later are a part of a bottom plate portion BT extending over the entire length in the first direction of the fin plate FP.

The second fin 302 is provided continuously on one side in the first direction of the first fin 301, and has the bottom plate portion 302A and a wall part 302B. The wall part 302B has a plate shape extending in the first direction and the third direction with the second direction as the thickness direction. The wall part 302B is provided continuously on one side in the first direction of the wall part 301B. The position of the wall part 302B on an end surface on one side in the third direction is on the other side in the third direction relative to the position of an end surface on one side in the third direction of the wall part 301B.

The bottom plate portion 302A is formed by being bent from the end portion on the other side in the third direction of the wall part 302B to one side in the second direction. Due to this, the second fin 302 has an L-shaped cross section in a cut surface orthogonal to the first direction. The function and the like of the second fin 302 will be described later.

The third fin 303 is provided continuously on the other side in the first direction of the first fin 301, and has the bottom plate portion 303A, a wall part 303B, and a top plate portion 303C. The wall part 303B has a plate shape extending in the first direction and the third direction with the second direction as the thickness direction. The wall part 303B is provided continuously on the other side in the first direction of the wall part 301B.

The bottom plate portion 303A is formed by being bent from the end portion on the other side in the third direction of the wall part 303B to one side in the second direction. The top plate portion 303C is formed by being bent from an end portion on one side in the third direction of the wall part 303B to one side in the second direction. The bottom plate portion 303A and the top plate portion 303C oppose each other in the third direction. Due to this, the third fin 303 has a U-shaped cross section in a cut surface orthogonal to the first direction. The position of the top plate portion 303C on an end surface on one side in the third direction is on the other side in the third direction relative to the position of the end surface on one side in the third direction of the wall part 301B. The function and the like of the third fin 303 will be described later.

The fin 40 has a first fin 401, a second fin 402, and a third fin 403, and is configured similarly to the fin 30 (FIG. 1). The fin 50 has a first fin 501, a second fin 502, and a third fin 503, and is configured similarly to the fin 30 (FIG. 1).

Note that the fin plate FP (FP1) hatched in FIG. 4 has only a part of the bottom plate portion BT between the fins 30 and 40 and between the fins 40 and 50. As shown in FIG. 4, some fin plates FP have not only a part of the bottom plate portion BT but also a coupling fin CF between the fins 30 and 40 and between the fins 40 and 50 (fin plate FP2). The coupling fin CF couples, in the first direction, a wall part (e.g., 302A) on the other side in the first direction and a wall part (e.g., 403A (FIG. 4)) on one side in the first direction.

In an end region R2 on the other side in the second direction (FIG. 3) in the heat dissipation fin part 10, the fin plate FP (first type fin plate FP1) not having the coupling fin CF as described above and the fin plate FP (second type fin plate FP2) having the coupling fin CF are alternately arranged in the second direction. As shown in FIG. 4, the fin plate FP (third type fin plate FP3) in which the third fin 303 has only the wall part 303B is arranged at an end portion on one side in the second direction in the end region R2 on the other side in the second direction. In the end region R2 on the other side in the second direction, the fin plates FP1, FP2, and FP3 are arranged in the second direction, whereby a plurality of the third fins 303 are arranged in the second direction at an end portion on the other side in the first direction in the end region R2 on the other side in the second direction. Due to this, an end portion fin group 3A is formed (FIG. 4).

In an end region R1 on one side in the second direction (FIG. 3) of the heat dissipation fin part 10, the fin plates FP1 and FP2 are alternately arranged in the second direction. At an end portion on one side in the second direction in the end region R1 on one side in the second direction, a fin plate FP4 (fourth type fin plate) having a flat plate shape extending in the first direction and the third direction with the second direction as the thickness direction is arranged (FIG. 3).

In the end region R1 on one side in the second direction, the fin plates FP1, FP2, and FP4 are arranged in the second direction, whereby the plurality of third fins 303 are arranged in the second direction at the end portion on the other side in the first direction in the end region R1 on one side in the second direction. Due to this, an end portion fin group 3B is formed (FIG. 1).

In a region between the end region R1 on one side in the second direction and the end region R2 on the other side in the second direction, fin plates FP5 and FP6 (fifth and sixth type fin plates) not having the third fin 303 on the other side in the first direction in the fin plates FP1 and FP2 are alternately arranged in the second direction (FIG. 4). Due to this, a recess portion 100 recessed to the other side in the third direction is formed between the end portion fin groups 3A and 3B (FIG. 1).

In this manner, the heat dissipation fin part 10 (fin groups 3, 4, and 5) is formed with various fin plates FP arranged in the second direction and integrated by, for example, caulking or the like. The formed heat dissipation fin part 10 is fixed to the surface 21 on one side in the third direction of the base portion 2 by brazing, for example. In this manner, by configuring the heat dissipation fin part 10 using the fin plate FP having a configuration in which the fins 30, 40, and 50 are integrated in the first direction, it is possible to increase the rigidity of the heat dissipator 1 and suppress deflection and the like due to flow of the refrigerant W even when the thickness of the base portion 2 is reduced for thermal conductivity.

With such a configuration, in the fin groups 3, 4, and 5, the refrigerant W flows through a flow path formed by the fins 30, 40, and 50 adjacent in the second direction. At this time, the refrigerant W flows on the bottom plate portion BT. When the fin plate FP is not provided with the bottom plate portion BT, the refrigerant W flows on the base portion 2. For example, in the case of the fin 30, the refrigerant W is guided along wall surfaces (surfaces orthogonal to the second direction) of the wall parts 303B, 301B, and 302B.

That is, the heat dissipator 1 includes the plurality of fins 30, 40, and 50 that protrude from the base portion 2 to one side in the third direction, extend in the first direction, are arranged in the second direction, and guide the refrigerant W along a surface intersecting the second direction.

The heat dissipator 1 has the plurality of fin groups 3, 4, and 5 that are configured by arranging, in the second direction, the plurality of fins 30, 40, and 50 that protrude from the base portion 2 to one side in the third direction and extend in the first direction, the plurality of fin groups 3, 4, and 5 being arranged side by side in the first direction.

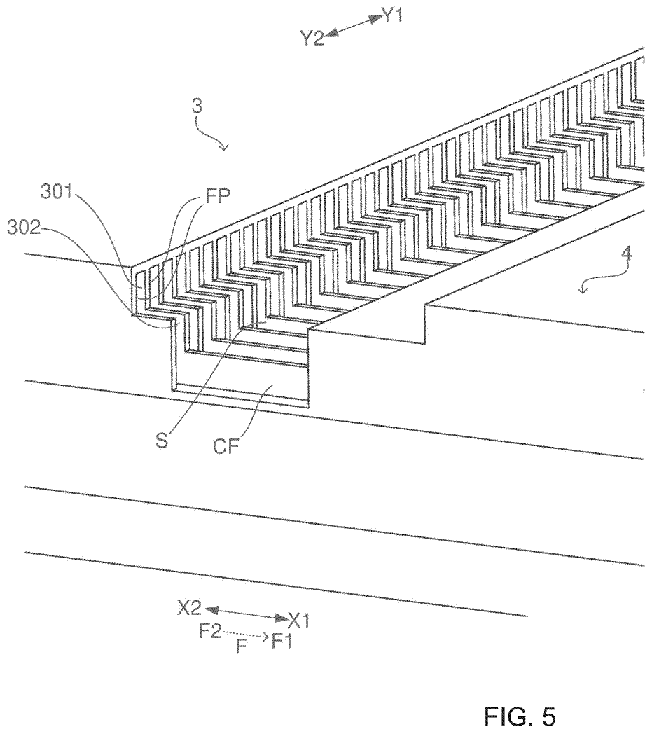

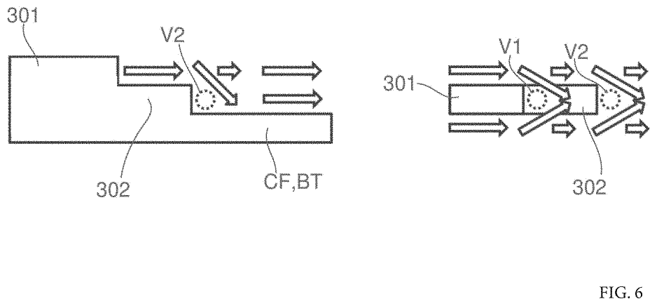

Next, in the fins 30 and 40, the second fins 302 and 402 arranged on the downstream side will be described more specifically. Here, the second fin 302 will be described as an example with reference to FIGS. 5 and 6, but the content of the second fin 402 is similar.

FIG. 5 is a partially enlarged view showing the configuration in the vicinity between the upstream side fin group 3 and the center fin group 4. As shown in FIG. 5, a plurality of the second fins 302 are arranged in the second direction. The position of the second fin 302 at the end on one side in the third direction is positioned on the other side in the third direction relative to the end on one side in the third direction of the flow path FP formed between the first fin 301 and the fin 30 adjacent to the first fin 301 in the second direction.

Here, FIG. 6 is a view schematically showing the flow of the refrigerant W in the vicinity of the second fin 302. The left side of FIG. 6 is a side view as viewed in the second direction, and the right side of FIG. 6 is a plan view as viewed in the third direction. The refrigerant W having flowed through the flow path FP in this manner can flow into a part of the second fin 302 on one side in the third direction, whereby a vortex V1 is generated at a boundary between the first fin 301 and the second fin 302. Therefore, mixing of the refrigerant W in the vicinity of the second fin 302 on one side in the third direction is facilitated.

Here, as shown in FIG. 3, since both ends in the second direction of the heating element 6A are arranged close to the center side in the second direction, heat transfer to the refrigerant W1 flowing through both end portions in the second direction of the fin group 3 is small, and the temperature of the refrigerant W1 is relatively low. On the other hand, heat transfer to a refrigerant W2 flowing on the center side in the second direction of the fin group 3 becomes large, and the temperature of the refrigerant W2 is relatively high. However, as described above, mixing of the refrigerants W1 and W2 is facilitated at a downstream side outlet of the fin group 3. This facilitates homogenization of the temperature of the refrigerant W, and can improve the cooling performance in the fin group 4 on a subsequent stage side.

As shown in FIG. 5, the coupling fin CF is formed between the second fin 302 and the fin 40 in the fin group 4 on the subsequent stage side, and a space is formed on one side in the third direction of the coupling fin CF. Alternatively, a space is formed between the second fin 302 and the fin 40 on the subsequent stage side without forming the coupling fin CF. A slot S is formed by the space formed as described above. The slot S has an effect of stopping the growth of a boundary layer in the fin to improve the cooling performance, an effect of mixing the refrigerant W discharged from the downstream side outlet of the fin group 3, and an effect of reducing pressure loss. By providing the coupling fin CF, it is possible to improve rigidity of the heat dissipator 1, and increase a contact area with the refrigerant W in the slot S to improve the cooling performance.

As shown in FIG. 6, the refrigerant W flows from one side in the third direction of the second fin 302 toward the coupling fin CF or the bottom plate portion BT, and the refrigerant W having flowed along the second fin 302 flows into one side in the third direction of the coupling fin CF or the bottom plate portion BT, thereby generating a vortex V2. Such vortex V2 facilitates mixing of the refrigerant W in the slot S. Therefore, the temperature of the refrigerant W is homogenized more, and the cooling performance in the fin group 4 on a subsequent stage side can be improved.

Since a turbulence generation effect is enhanced by the second fins 302 as described above, when the refrigerant W flows into the fin group 4 on the subsequent stage side due to the influence of the turbulence, the growth of the boundary layer is suppressed, and the cooling performance can be improved.

Next, the third fins 303, 403, and 503 arranged on the upstream side in the fins 30, 40, and 50 will be described more specifically.

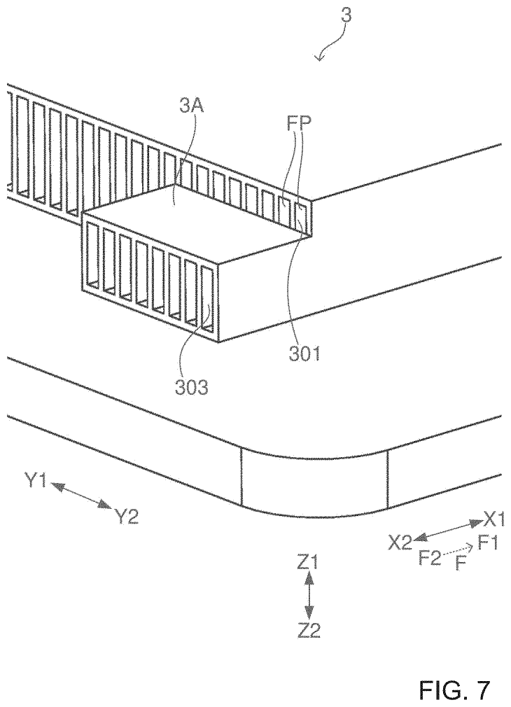

FIG. 7 is a partially enlarged view showing the configuration in the vicinity of the end portion fin group 3A in the upstream side fin group 3. The position of the third fin 303 at the end on one side in the third direction is on the other side in the third direction relative to the position of the end on one side in the third direction of the flow path FP formed on both sides of the first fin 301 in the second direction.

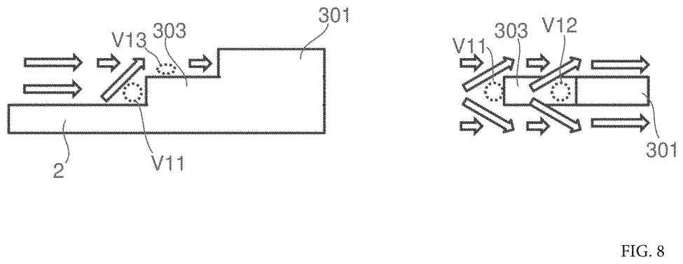

FIG. 8 is a view schematically showing a flow of the refrigerant W in the vicinity of the third fin 303. The left side of FIG. 8 is a side view as viewed in the second direction, and the right side of FIG. 8 is a plan view as viewed in the third direction. Thus, the refrigerant W having flowed on the base portion 2 flows into both sides of the third fin 303 in the second direction, whereby a vortex V11 is generated in the vicinity of the end on the other side in the first direction of the third fin 303. The refrigerant W having flowed on the third fin 303 flows into both sides of the first fin 301 in the second direction, whereby a vortex V12 is generated in the vicinity of the end on the other side in the first direction of the first fin 301. Since the refrigerant W having flowed on the base portion 2 flows into the end portion of the third fin 303 on the other side in the first direction on one side in the third direction, a vortex V13 is generated.

Thus, since by providing the third fin 303, the turbulence generation effect is enhanced, the rectification of the refrigerant W having flowed into the fin group 3 is delayed, and the growth of the boundary layer is suppressed, the cooling performance can be improved. The turbulence generation effect by the third fin 303 is higher than the effect by the second fin 302.

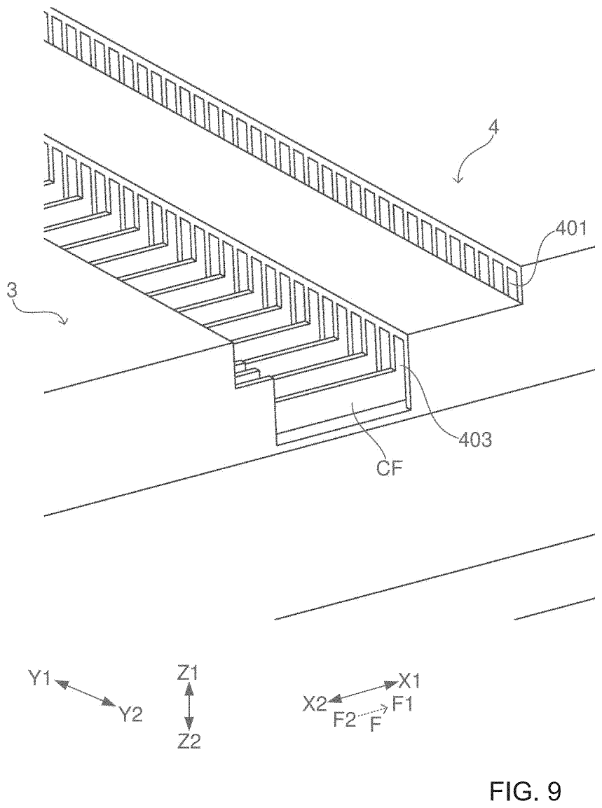

FIG. 9 is a partially enlarged view showing the configuration in the vicinity between the upstream side fin group 3 and the center fin group 4. By providing the third fin 403 in the fin group 4 shown in FIG. 9, similarly to the above effect, the vortex V11 is generated at the boundary between the coupling fin CF or the bottom plate portion BT and the third fin 403, and the vortices V12 and V13 are generated on one side in the third direction of the third fin 403. This enhances the turbulence generation effect, and improves the cooling performance by the refrigerant W having flowed into the fin group 4. Note that the third fin 503 in the fin 50 has the same effect.

Note that any of the fins 30, 40, and 50 does not need to have both the second fin and the third fin. Any of the fins 30, 40, and 50 may have only one of the second fin and the third fin.

That is, in the present example embodiment, at least any of the fins 30 has the first fin 301. The at least any fin 30 includes the second fin 302 that is provided continuously on one side in the first direction of the first fin 301, and has an end on one side in the third direction on the other side in the third direction relative to an end on one side in the third direction of the flow path FP formed between the first fin 301 and the fin 30 adjacent to the first fin 301 in the second direction, and the third fin 303 that is provided continuously on the other side in the first direction of the first fin 301, and has an end on one side in the third direction on the other side in the third direction relative to the end on one side in the third direction of the flow path FP.

The at least any of the fins 30 has the second fin 302. An interval in the first direction is formed between the second fin 302 and a subsequent stage fin 40 arranged on one side in the first direction of the second fin 302.

The heat dissipator 1 has the coupling fin CF that couples, in the first direction, at least any of the second fins 302 and the subsequent stage fin 40.

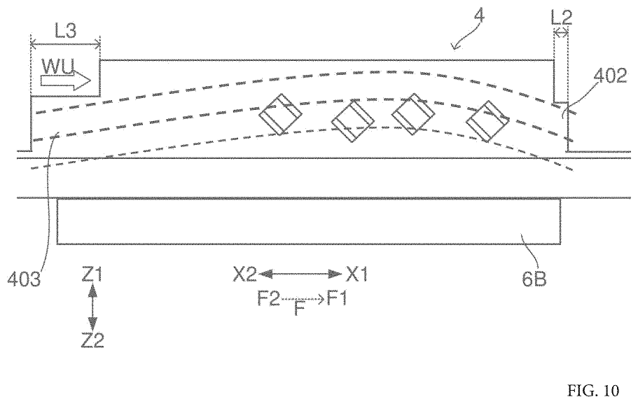

Here, FIG. 10 is a side view of the center fin group 4. As shown in FIG. 10, a first direction length L3 of the third fin 403 is longer than a first direction length L2 of the second fin 402. Since a refrigerant WU not subjected to heat exchange flows into the flow path formed by the fin 40 from one side in the third direction of the third fins 403, as indicated by an isotherm indicated by the broken line in FIG. 10, there is an effect of putting the peak of reduction in cooling performance on the downstream side of the center in the first direction of the fin 40. Therefore, it is possible to improve the cooling performance on the downstream side of the heating element 6B. Note that the effect by this configuration is the same for the downstream side fin group 5.

As described above, in the heat dissipation fin part 10, the end portion fin groups 3A and 3B are configured. On the downstream side of the downstream side fin group 5, the second fin 502 may constitute an end portion fin group in both end portions in the second direction.

That is, the heat dissipator 1 has an end portion fin group formed by the plurality of second fins 502 or third fins 303 adjacent to in the second direction and arranged in both end portions in the second direction in the fin groups 5 and 3 including the plurality of fins 50 and 30. The recess portion 100 recessed to the other side in the third direction is formed between the end portion fin groups. This allow the operator can suppress an error in the attaching direction when attaching the heat dissipator 1 by checking the recess portion 100.

Note that the end portion fin group is more desirably configured in the upstream side fin group 3. That is, the end portion fin groups 3A and 3B include the third fin 303, and the fin group 3 is arranged on the most other side in the first direction among the plurality of fin groups 3, 4, and 5 arranged in the first direction. Thus, by providing the recess portion 100 on the upstream side, flow path resistance on the center side in the second direction when the refrigerant W flows into the fin group 3 can be reduced, and the cooling performance of the heating element 6A positioned on center side in the second direction in the fin group 3 can be improved.

In other words, the end portion fin groups 3A and 3B arranged at both end portions in the second direction are provided at the end portion on the other side in the first direction of the fin group 3 arranged on the most other side in the first direction or at the end portion on one side in the first direction of the fin group 5 arranged on the most one side in the first direction, and the recess portion 100 recessed to the other side in the third direction is formed between the end portion fin groups 3A and 3B.

Then, the end portion fin groups 3A and 3B are desirably included in the fin group 3 arranged on the most other side in the first direction.

As shown in FIGS. 1 and 2, in the center fin group 4 and the downstream side fin group 5, spoilers 7 are formed in the fin 40 and 50.

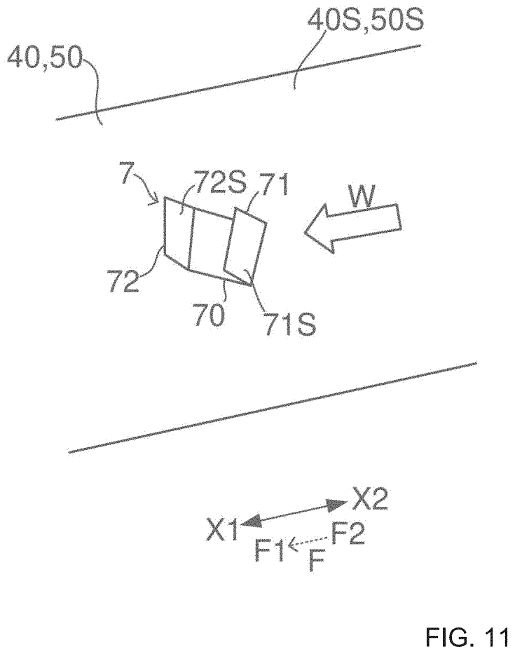

Here, FIG. 11 shows a perspective view showing a configuration example of the spoiler 7. The fins 40 and 50 have guide surfaces 40S and 50S that extend in the first direction and guide the refrigerant W. The spoiler 7 has an opening 70 penetrating the fins 40 and 50 in the second direction. The spoiler 7 has protrusions 71 and 72. The protrusions 71 and 72 are formed by being bent to one side in the same second direction at the edge of the opening 70, and oppose each other in the first direction. The opening 70 and the protrusions 71 and 72 can be formed by cutting and bending the fins 40 and 50. The protrusion 71 is arranged on the other side in the first direction relative to the protrusion 72.

The protrusions 71 and 72 have opposing surfaces 71S and 72S opposing each other in the direction where the refrigerant W flows, that is, one side in the first direction. The opposing surfaces 71S and 72S are included in the protrusions 71 and 72. The spoiler 7 has a function of preventing the flow of the refrigerant W by the opposing surfaces 71S and 72S. The turbulence of the refrigerant W is easily generated in the vicinity of the opposing surfaces 71S and 72S, and the cooling performance by the fins 40 and 50 can be improved.

The number of the protrusions is not limited to two, and may be one or three or more. That is, the spoiler 7 has at least one of the protrusion 71 or 72 protruding from the guide surfaces 40S and 50S in the second direction at the edge of the opening 70. The protrusions 71 and 72 can be easily formed as described above.

The at least one protrusion 71 or 72 is plural. Due to this, since the plurality of opposing surfaces 71S and 72S are provided, the number of places where the turbulence is generated can be increased, and the cooling performance can be further improved.

The protrusions 71 and 72 are inclined to one side in the first direction and the other side in the third direction. This makes it possible to guide the refrigerant W on the heating elements 6B and 6C side by the protrusions 71 and 72, and improve the cooling performance. Furthermore, two of the protrusions 71 and 72 are provided and protrude in the same direction. Due to this, the refrigerant W passes between the two protrusions 71 and 72 opposing each other, whereby the refrigerant W can be guided on the heating elements 6B and 6C side. The protrusions 71 and 72 may protrude in directions different from each other.

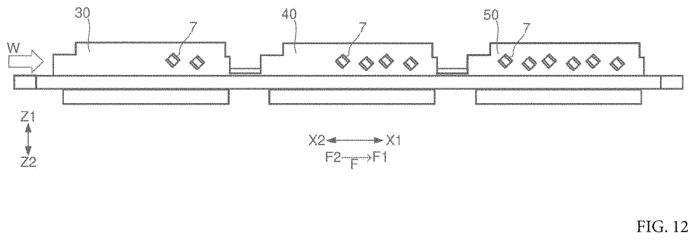

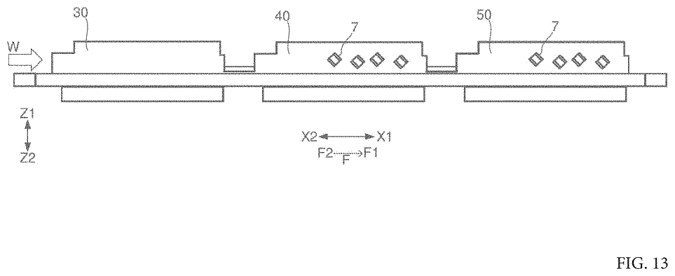

In the fin groups 4 and 5, for example, the spoilers 7 are provided in the fins 40 and 50 other than the fins 40 and 50 positioned at end on one side in the second direction, respectively. That is, at least any of the fins 40 and 50 included in at least any of the fin groups 4 and 5 has the spoiler 7. As shown in FIG. 2, for example, in the fins 30, 40, and 50 at the same second direction position, the numbers of spoilers 7 are 0, 4, and 6. For example, as shown in FIG. 12, in the fins 30, 40, and 50 at the same second direction position, the numbers of spoilers 7 may be adjusted after the spoilers 7 are provided in the fins 30 such as the numbers of spoilers 7 being 2, 4, and 6. Furthermore, for example, as shown in FIG. 13, in the fins 30, 40, and 50 at the same second direction position, the numbers of spoilers 7 may be the same on the downstream side, such as 0, 4, and 4.

That is, the numbers of spoilers 7 included in the fins 30, 40, and 50, respectively, at the same second direction position in the plurality of fin groups 3, 4, and 5 increase toward one side in the first direction. When the heating element are arranged in the first direction as the heating elements 6A, 6B, and 6C, since the temperature of the refrigerant W increases toward the downstream side, it is necessary to improve cooling performance on the downstream side. Therefore, since the number of spoilers 7 increases toward the downstream side, it is possible to improve the cooling performance on the downstream side for which the cooling performance should be improved, and to suppress the temperature difference among the heating elements 6A, 6B, and 6C.

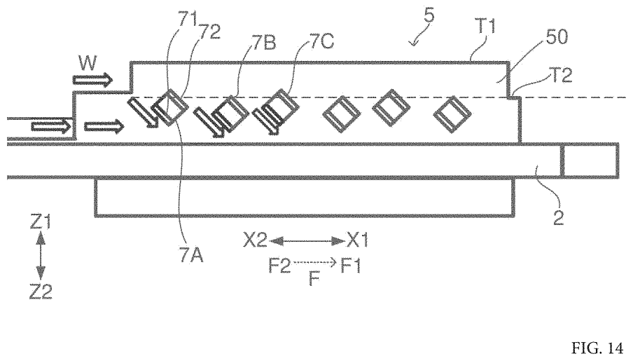

As shown in FIG. 14, in at least any of the fin groups 5, at least a part of the protrusion 72 on one side in the third direction is arranged on one side in the third direction relative to a fin end T2 that is an end on one side in the third direction positioned on the other side in the third direction relative to an end T1 on one side in the third direction on the most one side in the third direction in the fin 50 as viewed in the second direction, and at least a part of the protrusion 71 on the other side in the third direction is arranged on the other side in the third direction relative to the fin end T2.

As shown in FIG. 14, the spoilers 7 are alternately positioned in the order of one side in the third direction and the other side in the third direction toward one side in the first direction.

A spoiler 7A (high-position spoiler) on one side in the third direction positioned on the most upstream side forcibly guides, on the base portion 2 side the refrigerant W far from the base portion 2 on one side in the third direction. A spoiler 7B (low-position spoiler) on the other side in the third direction guides the refrigerant W so as to collide with the surface on the base portion 2 side. A spoiler 7C on one side in the third direction other than the most upstream side returns, to the base portion 2 side again, the refrigerant W having collided and bounced back on the surface on the base portion 2 side.

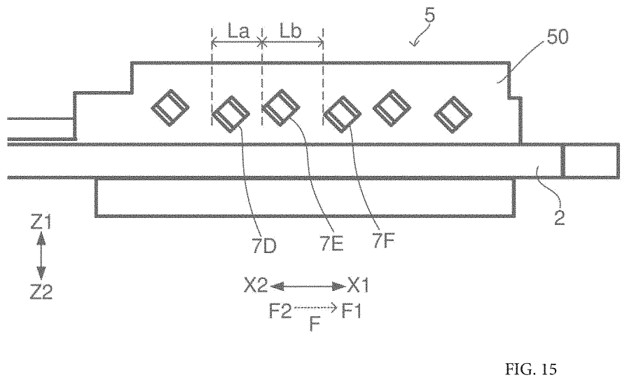

As shown in FIG. 15, in at least any of the fin groups 5, the spoilers 7 are alternately positioned in the third direction along the first direction, and a first direction interval La between spoilers 7D and 7E where the other side in the first direction is positioned on the other side in the third direction relative to one side in the first direction adjacent in the first direction is shorter than a first direction interval Lb between spoilers 7E and 7F where the other side in the first direction is positioned on one side in the third direction relative to one side in the first direction adjacent in the first direction.

Since the refrigerant W to be guided to the base portion 2 side by the spoiler 7D on the other side in the first direction vigorously bounces back on the surface on the base portion 2 side, the interval between the spoilers 7D and 7E needs to be shortened in order to guide the refrigerant W to the base portion 2 side again. Since the refrigerant W to be guided to the base portion 2 side by the spoiler 7E on one side in the first direction has less momentum when bouncing back than that of the refrigerant W to be guided to the base portion 2 side by the spoiler 7D on the other side in the first direction, the interval between the spoilers 7E and 7F may be long.

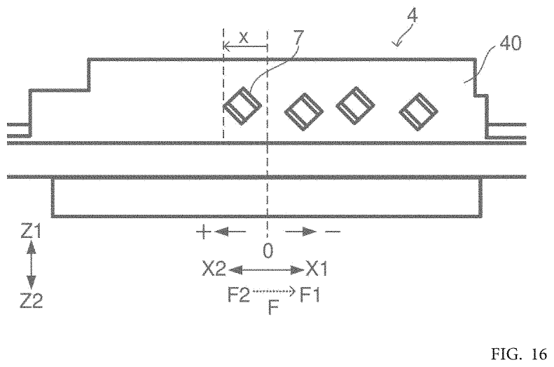

As shown in FIG. 16, with the center position of the fin 40 in the first direction being reference=0, the upstream side is set to +, and the downstream side is set to −. When the center of gravity (average) of a position x of each spoiler 7 in the fin 40 with respect to the reference is taken, the center of gravity is on the downstream side (−).

That is, in at least any of the fin groups 4, the center of gravity of the position of the spoiler 7 with respect to the first direction center position of the fin 40 is positioned on one side in the first direction relative to the first direction center position. This makes it possible to improve the cooling performance of the part on the downstream side for which the cooling performance in the heating element 6B overlapping the fin group 4 as viewed in the third direction should be improved.

As shown in FIG. 2, the spoiler 7 is not provided in the fin group 3 on the most upstream side. That is, the spoiler 7 arranged on the most other side in the first direction in the plurality of fin groups 3, 4, and 5 is included in the fin group 4 arranged on one side in the first direction relative to the fin group 3 on the most other side in the first direction. This makes it possible not to provide the spoiler 7 in the fin group 3 on the most upstream side that does not relatively require improvement in cooling performance. This makes it possible to reduce the processing cost for forming the spoiler 7.

In other words, in the plurality of fin groups 3, 4, and 5 arranged in the first direction, the fin group 4 including the plurality of fins 40 is arranged on one side in the first direction relative to the fin group 3 on the most other side in the first direction, and the spoiler 7 on the most other side in the first direction is arranged on the most other side in the first direction among the spoilers 7 arranged in the first direction in the plurality of fin groups 3, 4, and 5.

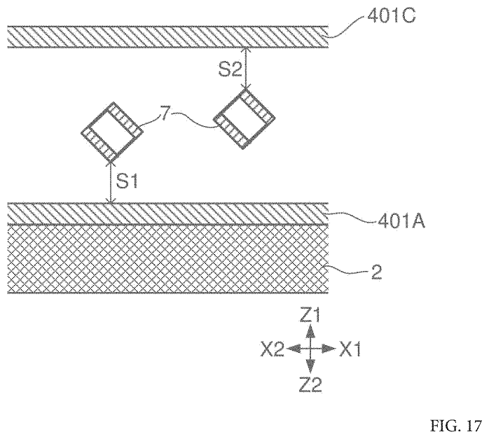

Here, securing of a gap between the spoiler 7 and the bottom plate portion and the top plate portion provided in the fin will be described. FIG. 17 is a view showing gaps S1 and S2 between the spoiler 7 and a bottom plate portion 401A and a top plate portion 401C provided in the fin 40, respectively. Note that the matters described below are also applied to the fins other than the fin 40.

The minimum gap between the gaps S1 and S2 needs to be set to a larger one of the gaps under the following conditions (1) and (2).

(1) Gap corresponding to the thickness of a gripping jig used for bending the bottom plate portion 401A and the top plate portion 401C

(2) Gap for preventing a flow path from being clogged by minute particles

For the above (1), the gap is 0.5 to 0.7 mm, for example. For the above (2), the gap is one desired by the user. For example, when the gap of the above (2) desired by the user is 1.0 mm, the minimum gap described above needs to be 1.0 mm even if the gap of the above (1) is 0.5 mm.

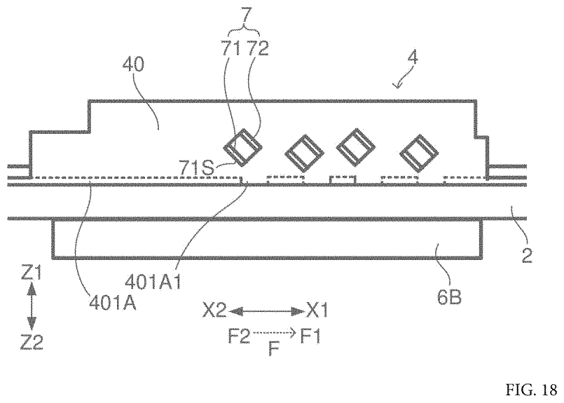

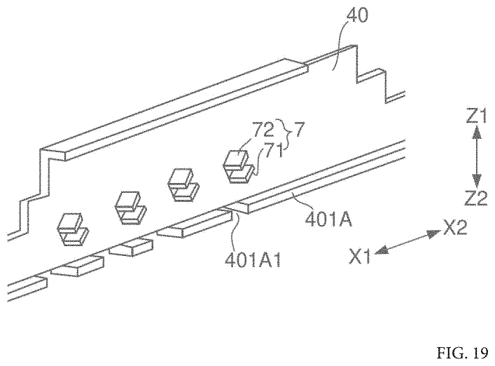

As described below, a bottom surface recess portion may be provided in the heat dissipator 1 with respect to the spoiler 7. FIG. 18 is a side view showing an example in which a bottom surface recess portion 401A1 is provided with respect to the spoiler 7 of the fin 40. FIG. 19 is a perspective view showing an example of the fin 40 provided with the bottom surface recess portion 401A1. The bottom surface recess portion 401A1 is provided as a notch in the bottom plate portion 401A bent in the second direction at the end portion on the other side in the third direction of the fin 40. Since the bottom surface recess portion 401A1 can be formed by providing a notch in the bottom plate portion 401A for fixing the fin 40 to the base portion 2 by brazing or the like, the bottom surface recess portion 401A1 can be easily formed. The bottom surface recess portion 401A1 is provided for each of the spoilers 7. As shown in FIG. 18, the base portion 2 is arranged on the other side in the third direction of the bottom plate portion 401A. Due to this, the bottom surface recess portion 401A as a notch has a shape recessed on the other side in the third direction. That is, the heat dissipator 1 has at least one bottom surface recess portion 401A1 that is arranged on the other side in the third direction relative to at least any of the spoilers 7 and is recessed on the other side in the third direction.

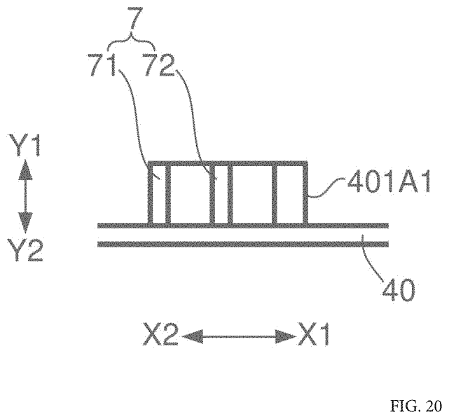

FIG. 20 shows an example of the bottom surface recess portion 401A1 and the spoiler 7 when viewed from one side in the third direction toward the other side in the third direction. In the example of FIG. 20, the second direction position of the entire spoiler 7 and the second direction position of the entire bottom surface recess portion 401A1 coincide with each other. That is, at least a part of the second direction position in at least any of the spoilers 7 and at least a part of the second direction position in at least one bottom surface recess portion 401A1 coincide with each other.

The boundary layer of the flow of the refrigerant W generated on one side surface in the third direction of the bottom plate portion 401A is destroyed by a discontinuous surface of the bottom surface recess portion 401A1, and the flow of the refrigerant W is brought into a state of floating from an end surface on the other side in the third direction of the bottom surface recess portion 401A1. Furthermore, the turbulence generated by the spoiler 7 joins the flow in the floating state, whereby the destruction of the boundary layer is facilitated. Therefore, it is possible to improve the cooling performance for cooling the heating element by the refrigerant W.

The spoilers 7 in the fin 40 form sets with the respective bottom surface recess portions 401A1. Similarly, the spoilers 7 in the fin 50 form sets with respective bottom surface recess portions. Therefore, as shown in FIG. 2 described above, since the number of spoilers 7 included in the fins 40 and 50 at the same second direction position increases toward one side in the first direction, the number of the sets for the fin 40 is larger than the number of the sets for the fin 50 at the same second direction position. That is, the number of sets of the spoiler 7 and the bottom surface recess portion 401A1 included in the fins 30, 40, and 50 at the same second direction position in the plurality of fin groups 3, 4, and 5, respectively, increases toward one side in the first direction. Since the number of sets of the spoiler 7 and the bottom surface recess portion 401A1 increases toward the downstream side, the cooling performance on the downstream side for which the cooling performance should be improved can be improved.

As shown in FIG. 20, a part of the bottom surface recess portion 401A1 overlaps a part of the spoiler 7 as viewed in the third direction. That is, at least a part of at least one bottom surface recess portion 401A1 overlaps at least a part of the spoiler 7 as viewed in the third direction. This makes it easy to cause the turbulence generated by the spoiler 7 to join the flow in the floating state, and makes it easy to destroy the boundary layer.

The bottom surface recess portions 401A1 that form sets with some spoilers 7 provided in the center fin group 4 overlap the heating element 6B (FIG. 3) as viewed in the third direction. Similarly, the bottom surface recess portions 401A1 that form sets with some spoilers 7 provided in the downstream side fin group 5 overlap the heating element 6C (FIG. 3) as viewed in the third direction. That is, at least a part of at least one bottom surface recess portion 401A1 overlaps the heating elements 6B and 6C that can be arranged on the other side in the third direction of the heat dissipator 1 as viewed in the third direction. This makes it possible to improve the cooling performance for cooling the heating elements 6B and 6C.

The opposing surface 71S (FIG. 18) of the protrusion 71 in the spoiler 7 is inclined to one side in the first direction and the other side in the third direction. That is, the opposing surface 71S of at least any of the spoilers 7 is inclined to one side in the first direction and the other side in the third direction. This makes it easy to guide the turbulence generated on the opposing surface 71S of the spoiler 7 to the bottom surface recess portion 401A1 side, and it is possible to further facilitate the destruction of the boundary layer.

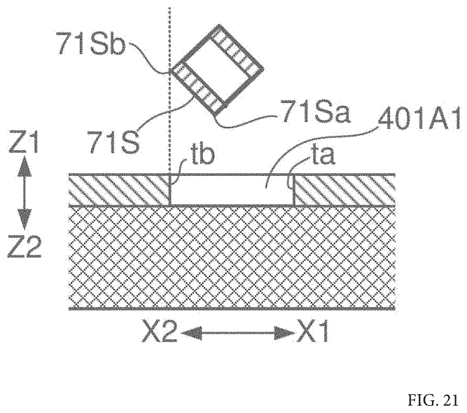

The positional relationship between the opposing surface 71S and the bottom surface recess portion 401A1 can take, for example, the following various forms. In the first form shown in FIG. 21, an end 71Sa on one side in the first direction of the opposing surface 71S is arranged on the other side in the first direction relative to an end portion ta on one side in the first direction of the bottom surface recess portion 401A1. The end 71Sb on the other side in the first direction of the opposing surface 71S is arranged at the same first direction position as an end portion tb on the other side in the first direction of the bottom surface recess portion 401A1.

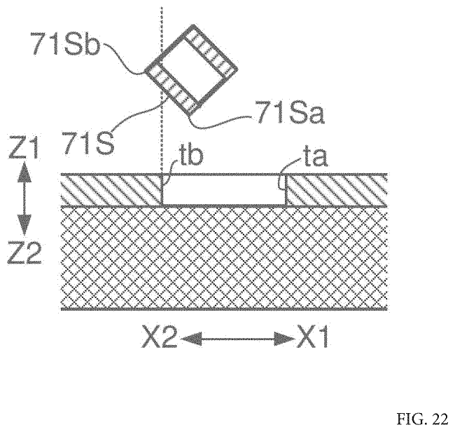

In the second form shown in FIG. 22, the end 71Sa on one side in the first direction of the opposing surface 71S is arranged on the other side in the first direction relative to an end portion ta on one side in the first direction of the bottom surface recess portion 401A1 and on one side in the first direction relative to the end portion tb on the other side in the first direction of the bottom surface recess portion 401A1. The end 71Sb on the other side in the first direction of the opposing surface 71S is arranged on the other side in the first direction relative to the end portion tb on the other side in the first direction of the bottom surface recess portion 401A1.

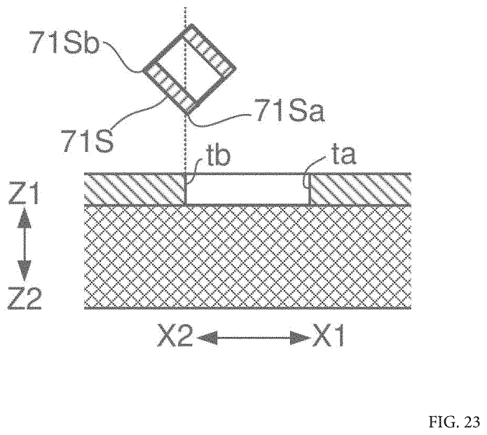

In the third form shown in FIG. 23, the end 71Sa on one side in the first direction of the opposing surface 71S is arranged at the same first direction position as the end portion tb on other side in the first direction of the bottom surface recess portion 401A1. The end 71Sb on the other side in the first direction of the opposing surface 71S is arranged on the other side in the first direction relative to the end portion tb on the other side in the first direction of the bottom surface recess portion 401A1.

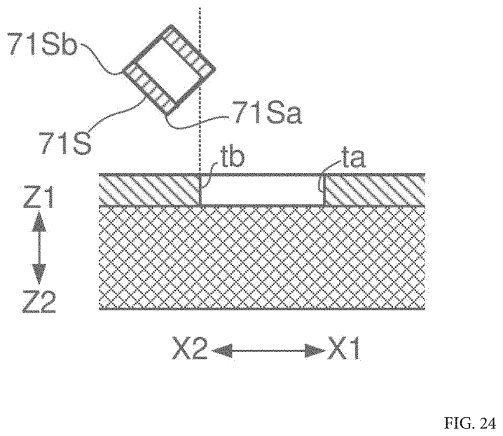

In the fourth form shown in FIG. 24, the end 71Sa on one side in the first direction and the end 71Sb on the other side in the first direction of the opposing surface 71S are arranged on the other side in the first direction relative to the end portion tb on the other side in the first direction of the bottom surface recess portion 401A1.

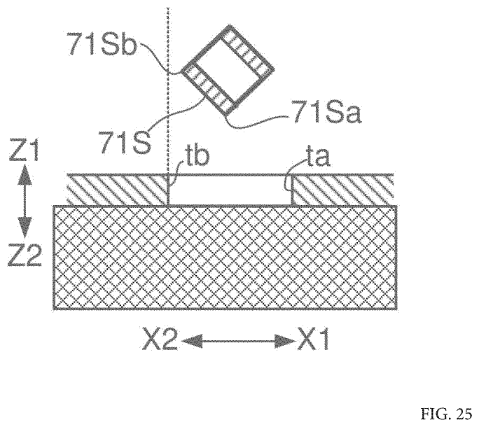

In the fifth form shown in FIG. 25, the end 71Sa on one side in the first direction and the end 71Sb on the other side in the first direction of the opposing surface 71S are arranged on one side in the first direction relative to the end portion tb on the other side in the first direction of the bottom surface recess portion 401A1 and on the other side in the first direction relative to an end portion ta on one side in the first direction of the bottom surface recess portion 401A1.

Therefore, in the first to fifth forms, the end 71Sa on one side in the first direction of the opposing surface 71S is arranged on the other side in the first direction relative to an end portion ta on one side in the first direction of the bottom surface recess portion 401A1. This makes it possible to arrange the downstream side end portion of the turbulence generated by the opposing surface 71S on the upstream side relative to the end portion ta on one side in the first direction of the bottom surface recess portion 401A1, and makes it easy to destroy the boundary layer.

In the first to third and fifth forms, the end 71Sa on one side in the first direction of the opposing surface 71S is arranged at the same first direction position as the end portion tb on the other side in the first direction of the bottom surface recess portion 401A1 or on one side in the first direction relative to the end portion tb on the other side in the first direction of the bottom surface recess portion 401A1. This makes it easy to arrange the downstream side end portion of the turbulence generated by the opposing surface 71S between both ends in the first direction of a bottom surface recess portion 23, and makes it easy to destroy the boundary layer.

In the first and fifth forms, the end 71Sb on the other side in the first direction of the opposing surface 71S is arranged at the same first direction position as the end portion tb on the other side in the first direction of the bottom surface recess portion 401A1 or on one side in the first direction relative to the end portion tb on the other side in the first direction of the bottom surface recess portion 401A1. It becomes easily to cause the turbulence generated by the opposing surface 71S to join the flow in the floating state, and easily destroy the boundary layer.

In the second to fourth forms, the end 71Sb on the other side in the first direction of the opposing surface 71S is arranged on the other side in the first direction relative to the end portion tb on the other side in the first direction of the bottom surface recess portion 401A1. This can facilitate the destruction of the boundary layer due to the turbulence generated by the opposing surface 71S.

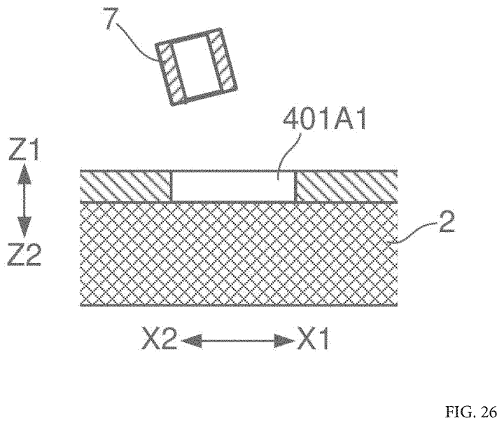

As shown in FIG. 26, the inclination angle with respect to the flow direction of the spoiler 7 may be substantially perpendicular. In this case, pressure loss increases under the condition of a certain flow rate, while the cooling effect increases. In view of the performance of the liquid pump to be used and the flow path resistance of the entire flow path, the inclination angle is only required to be determined after the allowable level of the pressure loss is determined.

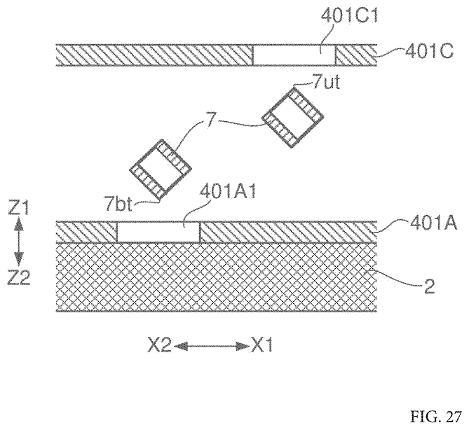

As shown in FIG. 27, in a case where an end 7bt on the other side in the third direction of the spoiler 7 opposes the bottom surface recess portion 401A1 in the third direction, by providing the bottom surface recess portion 401A1 in the bottom plate portion 401A, it is possible to bring the spoiler 7 close to the bottom plate portion 401A side in order to secure the same third direction flow path width. This can further improve the cooling performance. As shown in FIG. 27, a notch 401C1 opposing, in the third direction, an end Tut of the spoiler 7 on one side in the third direction can be provided in the top plate portion 401C. This makes it possible to bring the spoiler 7 close to the top plate portion 401C side in order to secure the same third direction flow path width. By narrowing the gap between the top plate portion 401C and the spoiler 7, the amount of the refrigerant W flowing between the top plate portion 401C and the spoiler 7 decreases, and the refrigerant W flowing in the vicinity of the top plate portion 401C is easily introduced to the bottom plate portion 401A side.

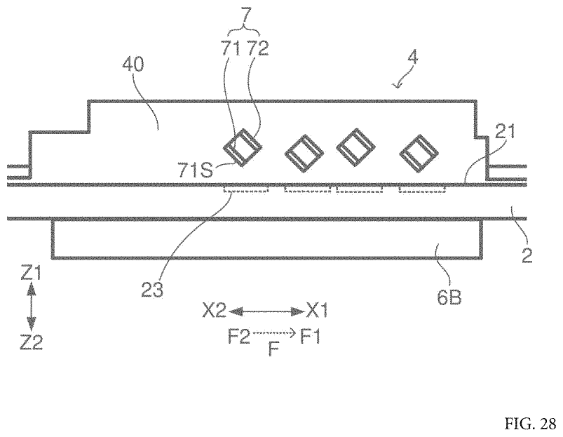

FIG. 28 is a side view showing an example in which the bottom surface recess portion is provided in the base portion 2. The bottom surface recess portion 23 shown in FIG. 28 is recessed from the surface 21 on one side in the third direction of the base portion 2 to the other side in the third direction. This makes it possible to provide the bottom surface recess portion in a case where the fin 40 is not provided with the bottom plate portion, and makes it possible to improve the cooling performance.

The example embodiment of the present disclosure has been described above. Note that the scope of the present disclosure is not limited to the above example embodiment. The present disclosure can be implemented by making various modifications to the above-described example embodiment without departing from the gist of the disclosure. The matters described in the above example embodiment can be arbitrarily combined together, as appropriate, as long as there is no inconsistency.

For example, a vapor chamber or a heat pipe may be provided between the heating element and the heat dissipator.

The present disclosure can be used for cooling various heating elements.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat dissipator comprising:
a plate-shaped base portion that extends in a first direction along a refrigerant flowing direction and in a second direction orthogonal to the first direction and has a thickness in a third direction orthogonal to the first direction and the second direction; and
fin groups including fins arranged in the second direction, protruding from the base portion to one side in the third direction and extending in the first direction, the fin groups being arranged side by side in the first direction; wherein
at least one of the fins included in at least one of the fin groups includes a spoiler that includes an opposing surface that opposes one side in the first direction that is a downstream side in the refrigerant flowing direction; and
a number of the spoilers included in each of the fins in a same second direction position in the fin groups increases toward the one side in the first direction.

2. The heat dissipator according to claim 1, wherein
the at least one of the fins includes a guide surface that extends in the first direction and guides the refrigerant;
the spoiler includes an opening that penetrates the at least one of the fins in the second direction and at least one protrusion that protrudes from the guide surface in the second direction at an edge of the opening; and
the opposing surface is included in the at least one protrusion.

3. The heat dissipator according to claim 2, wherein the at least one protrusion includes multiple protrusions.

4. The heat dissipator according to claim 2, wherein the at least one protrusion is inclined to the one side in the first direction and another side in the third direction.

5. The heat dissipator according to claim 4, wherein two of the protrusions are provided and protrude in a same direction.

6. The heat dissipator according to claim 5, wherein in at least any of the fin groups:
at least a portion of the at least one protrusion on the one side in the third direction is arranged on the one side in the third direction relative to a fin end that is an end on the one side in the third direction positioned on the other side in the third direction relative to an end on the one side in the third direction on a farthest one side in the third direction in the fin as viewed in the second direction; and
at least a portion of the at least one protrusion on the other side in the third direction is arranged on the other side in the third direction relative to the fin end.

7. The heat dissipator according to claim 6, wherein the spoilers are alternately positioned in an order of the one side in the third direction and the other side in the third direction toward the one side in the first direction.

8. The heat dissipator according to claim 4, wherein in at least any of the fin groups:
the spoilers are alternately positioned in the third direction along the first direction; and
a first direction interval between the spoilers where another side in the first direction is positioned on the other side in the third direction relative to the one side in the first direction adjacent in the first direction is shorter than a first direction interval between the spoilers where the other side in the first direction is positioned on the one side in the third direction relative to the one side in the first direction adjacent in the first direction.

9. The heat dissipator according to claim 1, wherein in at least any of the fin groups, a center of gravity of a position of the spoiler with respect to a first direction center position of the fin is positioned on the one side in the first direction relative to the first direction center position.

10. The heat dissipator according to claim 1, wherein the spoiler arranged farthest on the other side in the first direction in the fin groups is included in the fin group arranged on the one side in the first direction relative to the fin group on the farthest other side in the first direction.

11. The heat dissipator according to claim 1, further comprising:
end portion fin groups arranged at two end portions in the second direction at an end portion on another side in the first direction of the fin group arranged on a farthest other side in the first direction or at an end portion on the one side in the first direction of the fin group arranged on a farthest one side in the first direction; wherein
a recess portion recessed to another side in the third direction is provided between the end portion fin groups.

12. The heat dissipator according to claim 11, wherein the end portion fin group is included in the fin group arranged on the farthest other side in the first direction.

13. The heat dissipator according to claim 1, further comprising:
at least one bottom surface recess portion that is arranged on another side in the third direction relative to at least any of the spoilers and is recessed on the other side in the third direction; wherein
at least a portion of a second direction position in the at least any of the spoilers and at least a portion of a second direction position in the at least one bottom surface recess portion coincide with each other.

14. The heat dissipator according to claim 13, wherein the bottom surface recess portion is provided as a notch in a bottom plate portion bent in the second direction at an end portion on the other side in the third direction of the fin.

15. The heat dissipator according to claim 13, wherein the bottom surface recess portion is recessed from a surface on the one side in the third direction of the base portion to the other side in the third direction.

16. The heat dissipator according to claim 13, wherein the opposing surface of the at least any of the spoilers is inclined to the one side in the first direction and the other side in the third direction.

17. The heat dissipator according to claim 16, wherein an end on the one side in the first direction of the opposing surface is on the other side in the first direction relative to an end portion on the one side in the first direction of the bottom surface recess portion.

18. The heat dissipator according to claim 17, wherein the end on the one side in the first direction of the opposing surface is arranged at a same first direction position as an end portion on the other side in the first direction of the bottom surface recess portion or on the one side in the first direction relative to an end portion on another side in the first direction of the bottom surface recess portion.

19. The heat dissipator according to claim 16, wherein an end on another side in the first direction of the opposing surface is arranged at a same first direction position as an end portion on another side in the first direction of the bottom surface recess portion or on the one side in the first direction relative to the end portion on the other side in the first direction of the bottom surface recess portion.

20. The heat dissipator according to claim 16, wherein an end on another side in the first direction of the opposing surface is arranged on another side in the first direction relative to an end portion on the other side in the first direction of the bottom surface recess portion.

21. The heat dissipator according to claim 13, wherein a number of sets of the spoiler and the bottom surface recess portion included in the respective fins at a same second direction position in the plurality of fin groups increases toward the one side in the first direction.

22. The heat dissipator according to claim 13, wherein at least a portion of at least the one bottom surface recess portions overlaps a heater arranged on the other side in the third direction of the heat dissipator as viewed in the third direction.

23. The heat dissipator according to claim 13, wherein at least a portion of at least the one bottom surface recess portions overlaps at least a portion of the spoiler as viewed in the third direction.

24. The heat dissipator according to claim 1, wherein
a top plate portion bent in the second direction is provided at an end portion on the one side in the third direction of at least any of the fins; and
the top plate portion is provided with a top plate notch that opposes at least any of the spoilers in the third direction.
